(19) United States
(12) Patent Application Publication
(10) Pub. No.: US 2014/0027890 A1
(43) Pub. Date: Jan. 30, 2014

(54) Low Stress Package For an Integrated Circuit

(71) Applicant: Integrated Device Technology Inc., San Jose, CA (US)

(72) Inventor: Ajay K. Ghai, San Jose, CA (US)

(73) Assignee: Integrated Device Technology Inc., San Jose, CA (US)

(21) Appl. No.: 13/952,587

(22) Filed: Jul. 27, 2013

Related U.S. Application Data
(60) Provisional application No. 61/676,867, filed on Jul. 27, 2012.

(51) Int. Cl. H01L 23/00

(52) U.S. Cl. CPC H01L 23/562; H01L 24/85
USPC 257/669; 438/117

(57) ABSTRACT

A package that electrically connects an integrated circuit to a printed circuit board includes a frame and a package body that encases a portion of the frame and the integrated circuit. The frame includes a mounting region that is connected to the printed circuit board, and a cantilevering region that cantilevers away from the mounting region. The cantilevering region retains the integrated circuit in a flexible fashion.

### RELATED INVENTION

The application claims priority on U.S. Provisional Application Ser. Nos. 61/676,867 filed on Jul. 27, 2012, entitled “LOW STRESS NO-LEADS PACKAGE FOR AN INTEGRATED CIRCUIT”. As far as is permitted, the contents of U.S. Provisional Application Ser. No. 61/676,867 are incorporated herein by reference.

### BACKGROUND

Digital systems often include one or more integrated circuits (also referred to as “chips” or “dies”) that are coupled to a printed circuit board, using one or more packages. Typically, these packages are used to electrically and mechanically connect the integrated circuit to the printed circuit board.

One type of package is a flat, no-lead package. Unfortunately, existing flat, no-lead packages are not entirely satisfactory due to the coefficient of thermal expansion mismatch between the components of the flat, no-lead package and the integrated circuit. This mismatch can cause significant stress on the integrated circuit and deformation of the integrated circuit.

### SUMMARY

The present invention is directed to a package that electrically connects an integrated circuit to a printed circuit board. In one embodiment, the package includes a first frame and a package body that encases at least a portion of the first frame and the integrated circuit. The first frame includes a first mounting region that is electrically connected to the printed circuit board, and a first cantilevering region that cantilevers away from the first mounting region. Moreover, the package can include a first connector that connects the integrated circuit to the first cantilevering region so that the integrated circuit cantilevers away from the first frame. With this design, the integrated circuit is supported in a fashion that inhibits significant deformation of the integrated circuit.

Additionally, the package can include (i) a second frame having a second cantilevering region, and a second mounting region; (ii) a third frame having a third cantilevering region, and a third mounting region; and (iv) a fourth frame having a fourth cantilevering region, and a fourth mounting region. In this embodiment, the frames are spaced apart, encased by the package body, and support the integrated circuit in a fashion that inhibits significant deformation of the integrated circuit.

In one embodiment, each frame is made of electrically conductive material, and the frames independently electrically connect the integrated circuit to the printed circuit board.

In another embodiment, the package includes (i) one or more spaced apart frames, each having a mounting region that is connected to the printed circuit board, and a cantilevering region that engages the integrated circuit to retain the integrated circuit cantilevering away from the mounting region; and (ii) a package body that encases at least a portion of the one or more frame and the integrated circuit, the package body being made of an electrically isolating material.

In this embodiment, the package can include one or more separate connector wires that electrically connect the integrated circuit to the printed circuit board.

The present invention is also directed to an assembly that includes an integrated circuit and the package provided herein. Additionally, the assembly can include a printed circuit board that is electrically connected to the integrated circuit with the package.

In yet another embodiment, the present invention is directed to a method for electrically connecting an integrated circuit to a printed circuit board. In this embodiment, the method includes the steps of: (i) supporting the integrated circuit with a first frame that includes a first mounting region that engages the printed circuit board, and a first cantilevering region that cantilevers away from the first mounting region, the first cantilevering region engaging the integrated circuit to support the integrated circuit; and (ii) encasing at least a portion of the first frame and the integrated circuit with a package body that is made of an electrically isolating material.

### BRIEF DESCRIPTION OF THE DRAWINGS

The novel features of this invention, as well as the invention itself, both as to its structure and its operation, will be best understood from the accompanying drawings, taken in conjunction with the accompanying description, in which similar reference characters refer to similar parts, and in which:

FIG. 1A is a perspective view of an assembly including a printed circuit board, an integrated circuit, and a no-leads package having features of the present invention;

FIG. 1B is an exploded perspective view of a portion of the assembly of FIG. 1A;

FIG. 1C is a cut-away view of the no-leads package and integrated circuit 14 taken on line 1C-1C in FIG. 1A through the middle of the package including through two frames and the middle of the package body;

FIG. 1D is a cut-away view of the no-leads package and integrated circuit 14 taken on line 1D-1D in FIG. 1A in between frames;

FIG. 1E is a bottom view of the package;

FIG. 2A is a perspective view of another embodiment of an assembly including a printed circuit board, an integrated circuit, and a package having features of the present invention; and

FIG. 2B is a cut-away view taken on line 2B-2B in FIG. 2A.

### DESCRIPTION

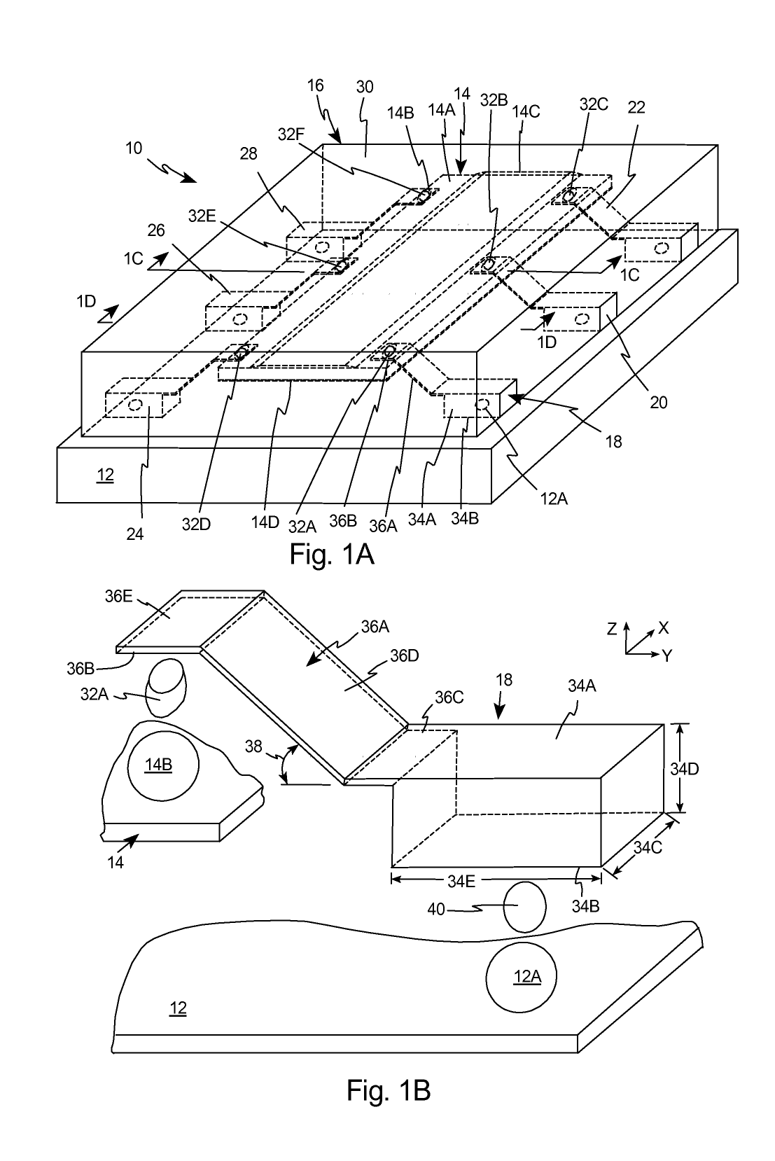

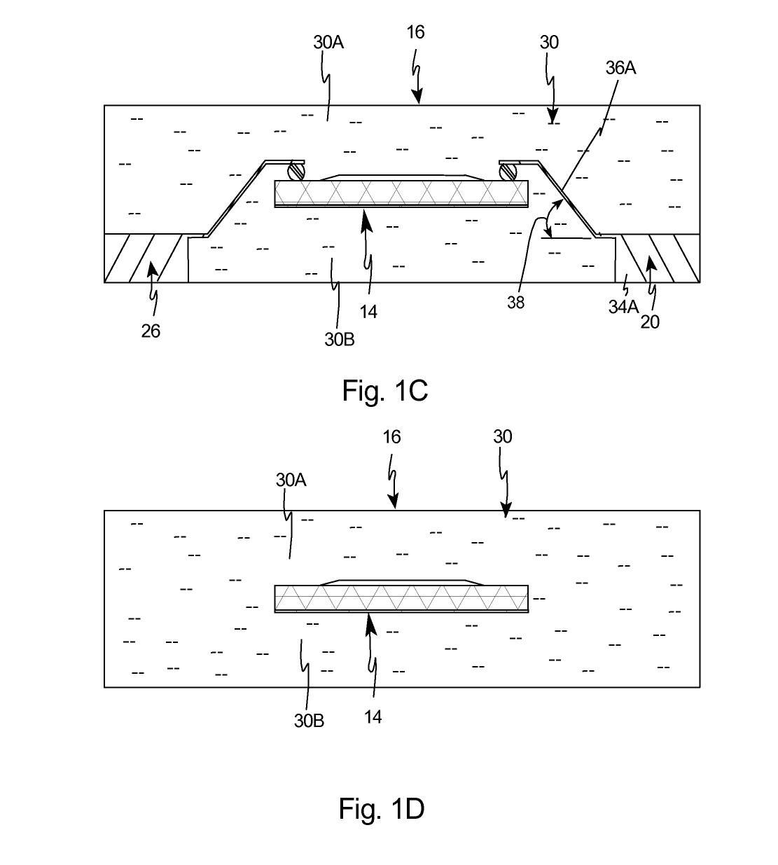

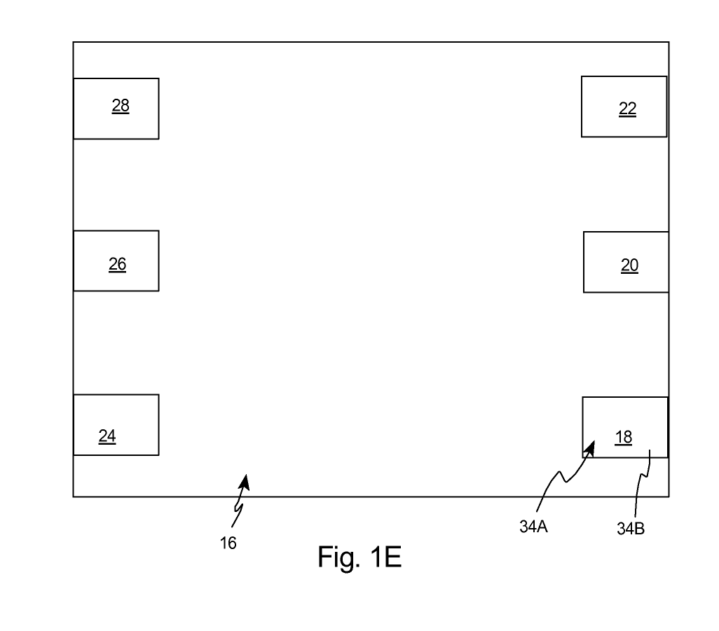

FIG. 1A is a perspective view of an assembly 10 that includes a printed circuit board 12, an integrated circuit 14 (illustrated in phantom), and a no-leads package 16 having features of the present invention that electrically and mechanically connects the integrated circuit 14 to the circuit board 12. The type of assembly 10 and the design of each of these components of the assembly 10 can vary pursuant to the teachings provided herein. Further, in certain alternative embodiments, the assembly 10 can include multiple integrated circuits 14 and multiple no-leads packages 16.

As an overview, the package 16 is uniquely designed to support the integrated circuit 14 in a fashion that inhibits significant deformation of the integrated circuit 14.

In one embodiment, the printed circuit board 12 is a flat board that is made of non-conducting material (e.g. an insulating material), and a plurality of predefined conductive metal pathways (not shown) that are printed on the surface of the board. In one embodiment, the printed circuit board 12 also includes a plurality of spaced apart, electrically conductive board contacts 12A (illustrated in phantom and sometimes referred to as board pads) that are electrically connected to the one or more integrated circuits 14 with one or more packages 16. In FIG. 1A, the printed circuit board 12 includes six board contacts 12A that are electrically connected to the one integrated circuit 14 with the one package 16. In this embodiment, the board contacts 12A are organized in two linear rows, with each row including three board contacts 12A. Alternatively, the printed circuit board 12 can be designed to include more than six or fewer than six board contacts 12A.

Additionally, in FIG. 1 A, each board contact 12A is illustrated as being circular shaped. Alternatively, the board contacts 12 can be another shape, such as rectangular.

Each integrated circuit 14 (only one is illustrated in FIG. 1A) consists of a number of circuit elements positioned on a chip of silicon crystal or other semiconductor material. The design of each integrated circuit 14 can vary. For example, each integrated circuit 14 can be a flip type chip or a wire bond type chip. In FIG. 1A, the integrated circuit 14 is a flip type chip that includes a circuit body 14A, and plurality of spaced apart, electrically conductive, chip contacts 14B (illustrated in phantom and sometimes referred to as chip pads) on the top of the circuit body 14A. In this embodiment, the chip contacts 14B are organized in two linear rows, with each row including three chip contacts 14B. Alternatively, the integrated circuit 14 can be designed to include more than six or fewer than six chip contacts 14B. For example, the integrated circuit 14 can be designed to include four chip contacts 14B.

Additionally, in FIG. 1A, each chip contact 14B is illustrated as being somewhat oval shaped. Alternatively, the chip contacts 14B can be another shape, such as circular or rectangular.

In one non-exclusive embodiment, the integrated circuit 14 can include a parylene side 14C on the top of the circuit body 14A, and a back metal EMI shield 14D on the bottom of the circuit body 14A. The parylene side 14C includes a variety of chemical vapor deposited on the circuit body 14A as a moisture and dielectric barrier. It should be noted that the integrated circuit 14 can be designed without one or both of the parylene side 14C and the EMI shield 14D.

The package 16 electrically and independently connects each of the chip contacts 14B on the integrated circuit 14 to a corresponding board contact 12A on the printed circuit board 12. Additionally, the package 16 can also fixedly secure the integrated circuit 14 to the printed circuit board 12 and provide mechanical support to the integrated circuit 14. The design of the package 16 can vary. For example, in FIG. 1A, the package 16 is a flat, no-leads package 16 that electrically connects the flip type chip 14 that includes six chip contacts 14B to the printed circuit board 12. Alternatively, the package 16 can be designed to electrically connect a chip having more than six or fewer than six chip contacts to the printed circuit board 12. For example, the package 16 can be a quad, flat, no-leads package 16 that electrically connects a flip type chip 14 having four chip contacts 14B to the printed circuit board 12. Still alternatively, the package 16 could be designed to electrically connect a wire bond type chip to the printed circuit board 12.

The size and shape of the package 16 will vary according to the size and shape of the integrated circuit 14. As non-exclusive examples, the package 16 can be generally rectangular in shape and can have (i) a height of between approximately 0.55 to 0.85 millimeters; (ii) a width of between approximately 1.62 to 5 millimeters; and (iii) a length of between approximately 2.5 to 7 millimeters. Alternatively, the package 16 can have dimensions different than that provided herein.

In FIG. 1A, the package 16 includes a plurality of frames 18-28 that are adapted to be electrically connected to the printed circuit board 12, a package body 30, and a plurality of electrical connectors 32A-32F (illustrated in phantom). In certain embodiments, the frames 18-28 mechanically and electrically connect the integrated circuit 14 to the printed circuit board 12. The number and design of the frames 18-28 can be varied to suit the design of the integrated circuit 14. In certain embodiments, the number of frames 18-28 is equal to the number of chip contacts 14B. For example, in FIG. 1A, the integrated circuit 14 includes six chip contacts 14B that are organized in two linear rows. In this embodiment, the package 16 includes six frames, that can be labeled, a first frame 18, a second frame 20, a third frame 22, a fourth frame 24, a fifth frame 26, and a sixth frame 28. Further, in this embodiment, the frames 18-28 are organized into two linear rows. Alternatively, if the integrated circuit 14 includes only four chip contacts, the package 16 can be designed to include only four frames.

In one embodiment, each frame 18-28 is electrically conductive and can include a mounting region 34A and a cantilevering region 36A that cantilevers away from the mounting region 34A. In this embodiment, for each frame 18-28, (i) the mounting region 34A includes a mounting pad 34B that is electrically connected to one of the board contacts 12A of the printed circuit board 12, and (ii) the cantilevering region 36A includes a cantilevering pad 36B that is electrically connected to one of the chip contacts 14B of the integrated circuit 14. For example, each frame 18-28 can be made of copper or another electrically conductive material. In this embodiment, the mounting region 34A is rigid and the cantilevering region 36A is flexible, and the regions 34A, 34B can be made as a unitary structure. Further, in this embodiment, the cantilevering regions 36A of of the frames 18-28 extend inward towards the integrated circuit 14.

In FIG. 1A, the mounting pad 34B for each frame 18-28 is exposed at the bottom adjacent to the circuit board 12 (and also optionally the back) of the package 16. Further, the mounting pads 34B can be organized into two linear rows of three mounting pads 34B. The arrangement of the mounting pads 34B can also be referred to as a pinout. With the present design, the frames 18-28 can be organized to have a standard pinout orientation.

The package body 30 encases, encircles and encloses the integrated circuit 14. Additionally, the package body 30 encases, encircles and encloses the majority of each frame 18-28. With this design, the package body 30 fixedly retains the frames 18-28 and the integrated circuit 14. Further, the package body 30 electrically isolates the frames 16-28 from each other. For example, the package body can be made of an electrically non-conductive (isolating) mold compound that is molded around the frames 18-28 and integrated circuit 14 after the frames 18-28 have been connected and fixedly secured to the integrated circuit 14. Suitable materials for the package body 30 include, but are not limited to, G700, and G770. In one non-exclusive embodiment, the package body 30 is generally rectangular shaped.

The plurality of electrical connectors 32A-32F mechanically and electrically connect the frames 18-28 to the chip contacts 14B of the integrated circuit 14. With this design, the number of electrical connectors 32A-32F is equal to the number of frames 18-28. Thus, in FIG. 1A, the package 16 includes six electrical connectors, namely (i) a first electrical connector 32A that electrically and mechanically connects the cantilevering pad 36B of the first frame 18 to one of the chip contacts 14B; (ii) a second electrical connector 32B that electrically and mechanically connects the cantilevering pad 36B of the second frame 20 to one of the chip contacts 14B; (iii) a third electrical connector 32C that electrically and mechanically connects the cantilevering pad 36B of the third frame 22 to one of the chip contacts 14B; (iv) a fourth electrical connector 32D that electrically and mechanically connects the cantilevering pad 36B of the fourth frame 24 to one of the chip contacts 14B; (v) a fifth electrical connector 32E that electrically and mechanically connects the cantilevering pad 36B of the fifth frame 26 to one of the chip contacts 14B; and (v) a sixth electrical connector 32F that electrically and mechanically connects the cantilevering pad 36B of the sixth frame 28 to one of the chip contacts 14B.

For example, each connector 32A-32F can be an electrically conductive, gold stud, solder, epoxy, or copper pillar bump that extends between the respective cantilevering pad and the respective chip contact. Each connector 32A-32F can include Anisotropic conductive epoxy, or Solder paste e.g. SnIn, SnSb, or SnAgCu paste but not limited to these materials of electrical connection.

With this design, (i) there is very small mechanical connection area between frames 18, 28 and the integrated circuit 14, and (ii) the connectors 32A-32F allow for relative movement between the frames 18, 28 and the integrated circuit 14. For example, in alternative, non-exclusive embodiments, the connection area between each frame 18-28 and the integrated circuit 14 can be less than approximately 500 um sq to 150000 sq um. As a result thereof, as the temperature of the assembly 10 changes, the amount of stress on the integrated circuit 14 and the amount of deformation on the integrated circuit caused by the different coefficients of thermal expansion of the frames 18, 28 and the integrated circuit 14 will be less.

FIG. 1B is an exploded perspective view of a portion of the assembly of FIG. 1A, including (i) a portion of the printed circuit board 12; (ii) a portion of the integrated circuit 14; (iii) the first frame 18; (iv) the first connector 32A that electrically and mechanically connects the cantilevering pad 36B of the first frame 18 to one of the chip contacts 14B of the integrated circuit 14; and (v) one of the board connectors 40 that electrically and mechanically connects the mounting pad 34B of the first frame 18 to one of the board contacts 12A of the circuit board 12.

It should be noted that the connection area between the first frame 18 and the integrated circuit 14 is relatively small because of the relatively small size of the first connector 32A. As a result thereof, as the temperature changes, the amount of stress on the integrated circuit 14 and the amount of deformation on the integrated circuit 14 caused by the different coefficients of thermal expansion of the frame 18 and the integrated circuit 14 will be less.

The design of each frame 18 (only the first frame is illustrated in FIG. 1B) can be varied to suit the design requirements of the integrated circuit 14 and the printed circuit board 12. The other frames 20-28 can be similar or slightly different from the first frame 18 illustrated in FIG. 1B.

As provided herein, in one embodiment, the first frame 18 includes the mounting region 34A and the cantilevering region 36A that are made of a unitary, electrically conductive material. In this embodiment, the mounting region 34A is generally rectangular block shape and the bottom of the mounting region 34A defines the generally flat mounting pad 34B that is electrically connected to one of the board contacts 12A. In one non-exclusive example, the mounting region 34A has (i) a width 34C (along the X axis) of between approximately 200 um and 350 um; (ii) a height 34D (along the Z axis) of between approximately 75 um and 200 um; and (iii) a length 34E (along the Y axis) of between approximately 300 um and 500 um.

The cantilevering region 36A is resilient, flexible and cantilevers at an angle away from the mounting region 34A. This design allows the cantilevering region 36A to deform slightly to reduce the stress applied to the integrated circuit 14 caused by temperature changes and the differences in coefficients of thermal expansions between the frames 18 and the integrated circuit 14.

In one embodiment, the cantilevering region 36A can be divided into three, relatively thin, rectangular shaped segments, namely a first cantilevering segment 36C, a second cantilevering segment 36D, and a third cantilevering segment 36E. In this embodiment, (i) the first cantilevering segment 36C is connected to and cantilevers generally horizontally away from the top of the mounting region 34A; (ii) the second cantilevering segment 36D (sometimes referred to as “an angled segment”) is connected to and cantilevers at an angle 38 (relative to horizontal, the mounting pad 34B, the top and bottom of the integrated circuit 14, and the top of the circuit board 12) away from a distal end of the first cantilevering segment 36, and (iii) the third cantilevering segment 36E is connected to and cantilevers generally horizontally away from a distal end of the second cantilevering segment 36D. With this design, a portion of the cantilevering region 36A cantilevers at the angle 38 away from the mounting region 34A.

Further, in this embodiment, the bottom of the cantilevering segment 36E defines the cantilevering pad 36B. With the present design, in certain embodiments, the cantilevering pad 36B is substantially parallel to and spaced apart (displaced) along the Z axis from the mounting region 34A.

The size of the angle 38 can be varied to suit the design of the integrated circuit 14. As a non-exclusive example, to achieve the same form factor for a package 16, a thicker integrated circuit 14 may require a steeper angle 38 than a thinner integrated circuit 14. Alternatively, a mounting on the bottom instead of the top of the integrated circuit 14 can require a less steep angle 38 to maintain the same form factor. In alternative, non-exclusive examples, the angle 38 can be between approximately 30 and 60 degrees, 40 and 50 degrees, 42 and 48 degrees, or 44 and 46 degrees. Alternatively, other angles 38 are possible.

In one non-exclusive example, (i) the first cantilevering segment 36C has a width (along the X axis) of between approximately 200 um and 350 um, a thickness (along the Z axis) of between approximately 50 um and 150 um, and a length (along the Y axis) of between approximately 50 um and 350 um; (ii) the second cantilevering segment 36D has a width (along the X axis) of between approximately 200 um and 300 um, a thickness of between approximately 50 um and 150 um, and (iii) a length of between approximately 50 and 350 um; and (iii) the third cantilevering segment 36E has a width (along the X axis) of between approximately 200 um and 300 um, a thickness of between approximately 50 um and 150 um, and (iii) a length of between approximately 50 and 350 um. Alternatively, other dimensions are possible.

FIG. 1C is a cut-away view of the no-leads package 16 and integrated circuit 14 taken on line 1C-1C (through two opposed frames 20, 26) in FIG. 1A and FIG. 1D is a cut-away view of the no-leads package 16 (in between the frames) and integrated circuit 14 taken on line 1D-1D in FIG. 1A. It should be noted that the circuit board 12 (illustrated in FIG. 1A) is not illustrated in FIGS. 1C and 1D. As provided above, in certain embodiments, the cantilevering regions 36A of the frames 20, 26 cantilever at the angle 38 away from the mounting region 34A. Further, the cantilevering regions 36A of the opposed frames 20, 26 extend towards each other.

FIG. 1C illustrates the very small mechanical connection area between the second frame 20 and the integrated circuit 14 via the second connector 32B, and the very small mechanical connection area between the fifth frames 26 and the integrated circuit 14 via the fifth connector 32E.

Also, as provided above, in certain embodiments, the integrated circuit 14 is fully encased and completely enclosed with the package body 30. As a result thereof, the package body 30 includes an upper portion 30A that is positioned above the integrated circuit 14, and a lower portion 30B that is positioned below the package body 30. In certain embodiments, the sizes of the portions 30A, 30B are designed to minimize the deformation to the integrated circuit 14 caused by the different coefficients of thermal expansion of the package body 30 materials, frame 26, and the integrated circuit 14. For example, the size of the portions 30A, 30B can be designed so that each portion 30A, 30B imparts an approximately equal in magnitude force on the integrated circuit 14 during thermal changes. For example, the package body 30 can be designed so that the integrated circuit 14 is positioned approximately near a center of the package body 30. Stated in another fashion, in one embodiment, the integrated circuit 14 is approximately centered in the middle of the package body 30, with the upper portion 30A and the lower portion 30B being approximately equal in size.

FIG. 1E is a bottom view of the package 16 of FIG. 1A. FIG. 1E illustrates that the mounting pad 34B for each frame 18-28 is exposed at the bottom of the package 16. It should be noted that the back of the mounting region 34A can also be exposed for ease of manufacturing. Further, the mounting pads 34B can be organized into two linear rows of three mounting pads 34B. The arrangement of the mounting pads 34B can also be referred to as a pinout. With the present design, the frames 18-28 can be organized to have a standard pinout orientation. Alternatively, the frames 18-28 can be organized to have a non-standard pinout orientation.

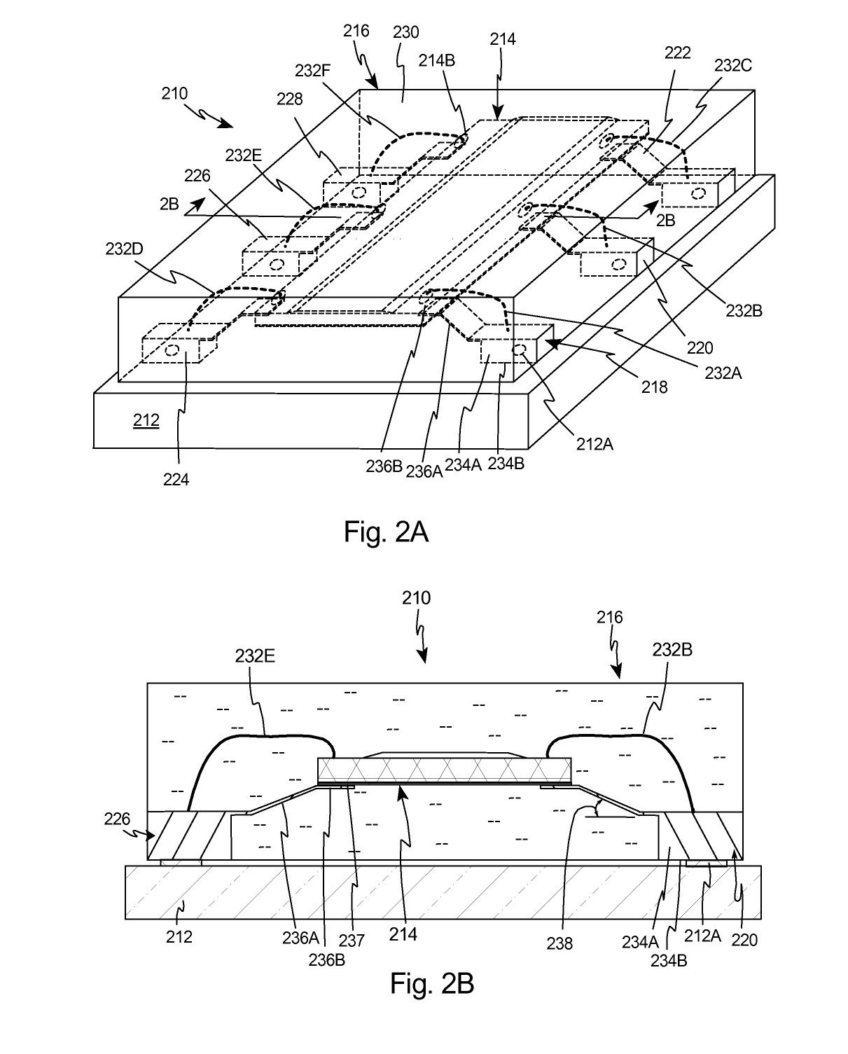

FIG. 2A is a perspective view and FIG. 2B is a cut-away view of another embodiment of an assembly 210 including a printed circuit board 212, an integrated circuit 214, and a package 216. In this embodiment, the printed circuit board 212, the integrated circuit 214 and the package 216 are somewhat similar to the corresponding components described above. However, in this embodiment, the integrated circuit 214 is wire bond type chip. Further, in this embodiment, the package 216 includes a plurality of frames 218-228, a package body 230, and a plurality of electrical connectors 232A-232F.

The frames 218-228 mechanically and electrically connect the integrated circuit 214 to the printed circuit board 212. In FIG. 2A, the integrated circuit 214 includes six chip contacts 214B that are organized in two linear rows. In this embodiment, the package 216 includes six frames, that can be referred to as a first frame 218, a second frame 220, a third frame 222, a fourth frame 224, a fifth frame 226, and a sixth frame 228. Further, in this embodiment, the frames 218-228 are organized into two linear rows. Alternatively, if the integrated circuit 214 includes only four chip contacts, the package 216 can be designed to include only four frames.

In this embodiment, each frame 218-228 is again electrically conductive and can include the mounting region 234A and the cantilevering region 236A that cantilevers away from the mounting region 234A. Again in this embodiment, the mounting region 234A is rigid and the cantilevering region 236A is flexible, and the regions 234A, 234B can be made as a unitary structure. Further, in this embodiment, the cantilevering regions 236A of the frames 218-228 extend inward towards the integrated circuit 214 to support the circuit 214 from the bottom of the circuit 214.

More specifically, in this embodiment, for each frame 218-228, the mounting region 234A includes a mounting pad 234B that is electrically connected to one of the board contacts 212A of the printed circuit board 212. However, in this embodiment, the cantilevering region 236A of each frame 218, 220 is positioned below the integrated circuit 214 to flexibly support the integrated circuit 214. In certain embodiments, a retainer 237 is used to secure the cantilevering pad 236B of the cantilevering region 236A to the bottom of the integrated circuit 214. As non-exclusive examples, the retainer 237 can be a non-conductive paste, epoxy, an adhesive, or film material.

Further, in this embodiment, (i) the first connector 232A is a wire that extends between the integrated circuit 214 and the mounting region 234A of the first frame 218, (ii) the second connector 232B is a wire that extends between the integrated circuit 214 and the mounting region 234A of the second frame 220; (iii) the third connector 232C is a wire that extends between the integrated circuit 214 and the mounting region 234A of the third frame 222, (iv) the fourth connector 232D is a wire that extends between the integrated circuit 214 and the mounting region 234A of the fourth frame 224; (v) the fifth connector 232E is a wire that extends between the integrated circuit 214 and the mounting region 234A of the fifth frame 226, and (vi) the sixth connector 232F is a wire that extends between the integrated circuit 214 and the mounting region 234A of the sixth frame 228. In this a separate frame 218-228 is used for each wire connector 232A-232F. Alternatively, for example, more than one wire connector can be used for the same frame.

It should be noted that the number of frames 218-228 and the number of wire connectors 232A-232F can be varied to suit the design of the integrated circuit 214.

Further, in this embodiment, the angle 238 of the cantilevering region 236A is smaller because of the wire bond type chip that is supported at the bottom of the chip 214. It is also appropriately designed to center the die 214 such that resulting stresses on die 214 are minimum.

While a number of exemplary aspects and embodiments of a package 16, 216 have been discussed above, those of skill in the art will recognize certain modifications, permutations, additions and sub-combinations thereof. It is therefore intended that the following appended claims and claims hereafter introduced are interpreted to include all such modifications, permutations, additions and sub-combinations as are within their true spirit and scope.

What is claimed is:

1. A package for electrically connecting an integrated circuit to a printed circuit board, the package comprising:
a first frame that includes a first mounting region that is adapted to be connected to the printed circuit board, and a first cantilevering region that cantilevers away from the first mounting region;
a first connector that connects the integrated circuit to the first cantilevering region; and
a package body that encases at least a portion of the first frame and the integrated circuit.

2. The package of claim 1 further comprising (i) a second frame that includes a second cantilevering region, and a second mounting region that is adapted to be electrically connected to the printed circuit board, the second frame being spaced apart from the first frame; and (ii) a second connector that connects the integrated circuit to the second cantilevering region; wherein the package body encases at least a portion for the second frame.

3. The package of claim 2 further comprising (i) a third frame that includes a third cantilevering region, and a third mounting region that is adapted to be electrically connected to the printed circuit board, the third frame being spaced apart from the first frame and the second frame; and (ii) a third connector that connects the integrated circuit to the third cantilevering region; wherein the package body encases at least a portion for the third frame.

4. The package of claim 3 further comprising (i) a fourth frame that includes a fourth cantilevering region, and a fourth mounting region that is adapted to be electrically connected to the printed circuit board, the fourth frame being spaced apart from the first frame, the second frame, and the third frame; and (ii) a fourth connector that connects the integrated circuit to the fourth cantilevering region; wherein the package body encases at least a portion for the fourth frame.

5. The package of claim 1 wherein the first frame is made of an electrically conductive material, wherein the first connector electrically connects the integrated circuit to the first cantilevering region, and wherein the package body includes a mold compound that is made of an electrically isolating material.

6. The package of claim 1 wherein the integrated circuit is completely enclosed by the package body.

7. The package of claim 6 wherein the integrated circuit is positioned approximately near a center of the package body.

8. The package of claim 1 wherein, the cantilevering region includes an angled segment that is at an angle of between approximately thirty and sixty degrees relative to the mounting region.

9. An assembly comprising an integrated circuit and the package of claim 1 electrically connected to the integrated circuit.

10. A package for electrically connecting an integrated circuit to a printed circuit board, the package comprising:
a first frame that includes a first mounting region that is adapted to be connected to the printed circuit board, and a first cantilevering region that cantilevers away from the first mounting region, the first cantilevering region engaging the integrated circuit to retain the integrated circuit cantilevering away from the first mounting region; and
a package body that encases at least a portion of the first frame and the integrated circuit, the package body being made of an electrically isolating material.

11. The package of claim 10 further comprising a first connector wire that electrically connects the integrated circuit to the printed circuit board.

12. The package of claim 11 further comprising (i) a second frame that includes a second cantilevering region, and a second mounting region that is adapted to be connected to the printed circuit board, the second cantilevering region engaging the integrated circuit to retain the integrated circuit cantilevering away from the second mounting region; and (ii) a second connector wire that electrically connects the integrated circuit to the printed circuit board.

13. The package of claim 12 further comprising (i) a third frame that includes a third cantilevering region, and a third mounting region that is adapted to be connected to the printed circuit board, the third cantilevering region engaging the integrated circuit to retain the integrated circuit cantilevering away from the third mounting region; and (ii) a third connector wire that electrically connects the integrated circuit to the printed circuit board.

14. The package of claim 10 wherein the first frame is adapted to electrically connect the printed circuit board to the integrated circuit.

15. The package of claim 10 wherein the cantilevering region includes an angled segment that is at an angle of between approximately thirty and sixty degrees relative to the mounting region.

16. An assembly comprising an integrated circuit, a printed circuit board, and the package of claim 10 electrically connecting the integrated circuit to the printed circuit board.

17. A method for electrically connecting an integrated circuit to a printed circuit board, the comprising the steps of:
supporting the integrated circuit with a first frame that includes a first mounting region that engages the printed circuit board, and a first cantilevering region that cantilevers away from the first mounting region, the first cantilevering region engaging the integrated circuit to support the integrated circuit; and
encasing at least a portion of the first frame and the integrated circuit with a package body that is made of an electrically isolating material.

18. The method of claim 17 further comprising the step of electrically connecting the integrated circuit to the printed circuit board with a first connector wire.

19. The method of claim 18 further comprising the steps of (i) supporting the integrated circuit with a second frame that includes a second mounting region that engages the printed circuit board, and a second cantilevering region that cantilevers away from the second mounting region, the second cantilevering region engaging the integrated circuit to support the integrated circuit; and electrically connecting the integrated circuit to the printed circuit board with a second connector wire.

20. The method of claim 17 wherein the first frame electrically connects the printed circuit board to the integrated circuit.
